(19) United States
(12) Patent Application Publication
(10) Pub. No.: US 2015/0351240 A1
(43) Pub. Date: Dec. 3, 2015

(54) PRINT SUBSTRATE, ELECTRONIC DEVICE, AND METHOD OF MANUFACTURING PRINT SUBSTRATE

(71) Applicant: FUJITSU LIMITED, Kawasaki-shi (JP)

(72) Inventor: Yoshio NABEYAMA, Yokohama (JP)

(21) Appl. No.: 14/700,266

(22) Filed: Apr. 30, 2015

(30) Foreign Application Priority Data
May 28, 2014 (JP) 2014-110244

(51) Int. Cl. H05K 1/11; H05K 3/00; H05K 1/02

(52) U.S. Cl. CPC H05K 1/115; H05K 1/0298; H05K 3/0091; H05K 2201/095; H05K 2203/163

(57) ABSTRACT

A print substrate includes: a base; a tapered shape hole that is formed in the base, and is configured to have a diameter which continuously changes along a thickness direction of the base; a conductive film that covers a wall surface of the tapered shape hole; a plurality of wirings that are formed in locations which are different from each other in the thickness direction of the base, and that are connected to the conductive film; and a cylindrical shape hole that communicates with the tapered shape hole on a smaller diameter side of the tapered shape hole, and that has a smaller diameter than the diameter of the tapered shape hole in the locations in which the wirings, formed on the smaller diameter side of the tapered shape hole, of the plurality of wirings are connected to the conductive film.

### CROSS-REFERENCE TO RELATED APPLICATION

This application is based upon and claims the benefit of priority of the prior Japanese Patent Application No. 2014-110244, filed on May 28, 2014,the entire contents of which are incorporated herein by reference.

### FIELD

The embodiments discussed herein are related to a print substrate, an electronic device, and a method of manufacturing the print substrate.

### BACKGROUND

For example, technologies below are known as a print substrate that has a multilayer wiring structure.

A circuit board is known in which a first dielectric substrate formed with stripe lines is interlayer-connected to a second dielectric substrate formed with micro stripe lines. In the first dielectric substrate, a through hole which has an approximately truncated (beheaded) cone shape is formed and the smaller diameter side of the through hole is connected to the stripe lines. In the second dielectric substrate, the plural micro stripe lines, which are connected to the larger diameter side of the through hole, are consecutively connected.

In addition, a method of manufacturing a multilayer printed wiring board, which includes steps below, is known. A hole having a small diameter is caused to pass through a multilayer printed wiring board, and a hole having a large diameter is made to the prescribed depth of the wiring board in the same location. Subsequently, after conduction is performed between upper and lower surfaces using a plating method or the like, the conduction between the upper and lower holes are cut off by cutting and removing the bottom of the large diameter using a drill having a diameter which is larger than the small diameter and smaller than the large diameter of the holes.

In the print substrate that has the multilayer wiring structure, a via hole is used to connect wirings which are formed different layers. There is a case in which a part of the via hole forms the branch path, called a stub, of wirings. Accordingly, there is a case in which a signal flowing through a signal line may be undesirably effected. That is, a signal flowing through the signal line is separated into two groups when reaching the branch point between the stub and the signal line. One of them heads to the stub, is reflected at the end of the stub, and returns to the branch point again. Therefore, there is a case in which the signal flowing through signal line and the signal reflected at the end of the stub interfere with each other, and thus signals are attenuated at the branch point. The problem is particularly remarkable when a high frequency signal is treated.

As a method of removing the stub, a back-drill method is known in which the stub is cut and removed by inserting a drill from the surface of the print substrate in a location at which a via hole, which forms the stub, is formed. However, in the back-drill method, it is difficult to appropriately remove the stub due to the problem of the location accuracy of the drill in the stroke direction. That is, the insertion depth of the drill in the print substrate varies because a drill attachment location is deviated from a standard location when the drill is attached to a machine tool.

For example, when the attachment location of the drill with regard to the machine tool in the stroke direction is deviated to a downward side (print substrate side) from the standard location, there is a case in which the insertion depth of the drill in the print substrate is deeper than an aimed depth, and thus a signal wiring is cut together with the stub. In contrast, when the attachment location of the drill with regard to the machine tool in the stroke direction is deviated to the upper side of the standard location (side opposite to the print substrate), there is a case in which the insertion depth of the drill in the print substrate is more shallow than the aimed depth, and thus it is difficult to completely remove the stub.

As described above, in the related art method, it is difficult to ensure the location accuracy of the drill in the stroke direction due to the variation in the attachment states of the drill for removing the stub with regard to the machine tool, and thus it is difficult to appropriately remove the stub.

The following are reference documents.
[Document 1] Japanese Laid-open Patent Publication No. 2013-120781 and
[Document 2] Japanese Laid-open Patent Publication No. 05-347480.

### SUMMARY

According to an aspect of the invention, a print substrate includes:

a base; a tapered shape hole that is formed in the base, and is configured to have a diameter which continuously changes along a thickness direction of the base; a conductive film that covers a wall surface of the tapered shape hole; a plurality of wirings that are formed in locations which are different from each other in the thickness direction of the base, and that are connected to the conductive film; and a cylindrical shape hole that communicates with the tapered shape hole on a smaller diameter side of the tapered shape hole, and that has a smaller diameter than the diameter of the tapered shape hole in the locations in which the wirings, formed on the smaller diameter side of the tapered shape hole, of the plurality of wirings are connected to the conductive film.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a cross-sectional diagram illustrating the partial configuration of a print substrate according to an embodiment of the disclosed technology;

FIG. 1B is a perspective view illustrating the partial configuration of the print substrate according to the embodiment of the disclosed technology;

FIGS. 2A to 2C are cross-sectional diagrams illustrating a method of manufacturing the print substrate according to the embodiment of the disclosed technology;

FIGS. 3A and 3B are cross-sectional diagrams illustrating the method of manufacturing the print substrate according to the embodiment of the disclosed technology;

FIG. 4 is a diagram illustrating three cases in which the attachment states of a drill, used to manufacture the print substrate according to the embodiment of the disclosed technology, with regard to the machine tool in a stroke direction are different from each other;

FIG. 5 is a diagram illustrating insertion depths, which correspond to cases 1 to 3 illustrated in FIG. 4, of the drill with regard to a base;

FIG. 6 is a diagram illustrating a method of removing a stub using the drill, which has the same diameter, in three cases in which the depth locations of wirings, formed on the smaller diameter side of a tapered shape hole part, are different from each other;

FIG. 7 is a diagram illustrating the method of removing the stub using the drill, which has the same diameter, in three cases in which the depth locations of the wirings, formed on the smaller diameter side of the tapered shape hole part, are different from each other;

FIG. 8 is a diagram illustrating a method of calculating the diameter of the drill used to manufacture the print substrate according to the embodiment of the disclosed technology;

FIGS. 9A to 9D are cross-sectional diagrams illustrating the method of manufacturing the print substrate according to the embodiment of the disclosed technology;

FIGS. 10A to 10C are cross-sectional diagrams illustrating the method of manufacturing the print substrate according to the embodiment of the disclosed technology;

FIG. 11A is a cross-sectional diagram illustrating the partial configuration of a print substrate according to a comparative example;

FIG. 11B is a perspective view illustrating the partial configuration of the print substrate according to the comparative example;

FIGS. 12A to 12C are cross-sectional diagrams illustrating a method of manufacturing the print substrate according to the comparative example;

FIGS. 13A and 13B are cross-sectional diagrams illustrating the method of manufacturing the print substrate according to the comparative example;

FIG. 14 is a diagram illustrating three cases in which the attachment states of the drill, used to manufacture the print substrate according to the comparative example, with regard to the machine tool in the stroke direction are different from each other;

FIG. 15 is a cross-sectional diagram illustrating the method of manufacturing the print substrate according to the embodiment of the disclosed technology;

FIGS. 16A to 16C are cross-sectional diagrams illustrating the method of manufacturing the print substrate according to the comparative example;

FIGS. 17A to 17C are cross-sectional diagrams illustrating the method of manufacturing the print substrate according to the comparative example;

FIG. 18A is a cross-sectional diagram illustrating the partial configuration of the print substrate according to the embodiment of the disclosed technology;

FIG. 18B is a perspective view illustrating the partial configuration of the print substrate according to the embodiment of the disclosed technology;

FIGS. 19A to 19C are cross-sectional diagrams illustrating the method of manufacturing the print substrate according to the embodiment of the disclosed technology;

FIGS. 20A to 20C are cross-sectional diagrams illustrating the method of manufacturing the print substrate according to the embodiment of the disclosed technology;

FIG. 21 is a perspective view illustrating the configuration of an electronic unit according to the embodiment of the disclosed technology;

FIG. 22A is a perspective view illustrating the configuration of an electronic device according to the embodiment of the disclosed technology; and

FIG. 22B is a perspective view illustrating the plural electronic units that are included in the electronic device according to the embodiment of the disclosed technology.

### DESCRIPTION OF EMBODIMENTS

Hereinafter, examples according to the embodiment of the disclosed technology will be described with reference to the accompanying drawings. Meanwhile, the same reference numerals are attached to the same or equivalent components and parts.

### First Embodiment

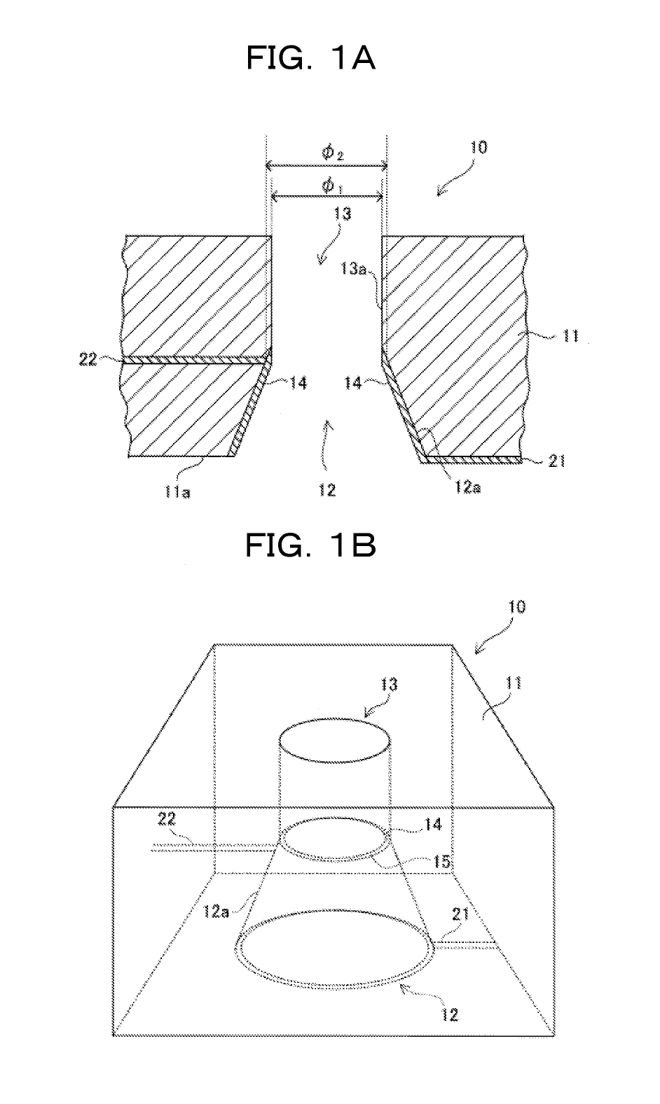

FIG. 1A is a cross-sectional diagram illustrating the partial configuration of a print substrate 10 according to a first embodiment of the disclosed technology. FIG. 1B is a perspective view illustrating the partial configuration of the print substrate 10.

The print substrate 10 has a multilayer wiring structure which includes plural wiring layers. In the embodiment, a wiring 21 is formed on the bottom surface 11a of a base 11, and a wiring 22 is formed inside of the base 11. It is possible to use a glass epoxy substrate, acquired in such a way that a laminated body in which cloth made of glass fiber is laminated is impregnated with an epoxy resin, as an example of the base 11. Meanwhile, the material of the base 11 is not particularly limited, and it is possible to use a well-known material of a paper phenol substrate, a paper epoxy substrate, a glass composite substrate, or the like.

The print substrate 10 includes a tapered shape hole part 12 that has a diameter which continuously changes along the thickness direction of the base 11. That is, the tapered shape hole part 12 changes such that the diameter continuously becomes small toward the inside of the base 11 from the bottom surface 11a of the base 11. As illustrated in FIG. 1B, the tapered shape hole part 12 has a truncated cone shape. The tapered shape hole part 12 forms a via hole.

The print substrate 10 includes a cylindrical shape hole part 13 that communicates with the tapered shape hole part 12. The cylindrical shape hole part 13 is formed to be concentric with the tapered shape hole part 12, and has a diameter φ₁ which has the same size as a diameter at the small diameter-side end of the tapered shape hole part 12. The tapered shape hole part 12 and the cylindrical shape hole part 13 form a through hole which passes through the base 11.

The wall surface 12a of the tapered shape hole part 12 is covered by a conductive film 14 which is formed of an electric conductor such as copper. The wall surface 13a of the cylindrical shape hole part 13 is not formed with the conductive film, and the base 11, which is an insulator, is exposed.

The wiring 21, which is formed on a wiring layer on the larger diameter side of the tapered shape hole part 12, is connected to the conductive film 14 at the opening end of the tapered shape hole part 12. In contrast, the wiring 22, which is formed on a wiring layer on the smaller diameter side of the tapered shape hole part 12, is connected to the conductive film 14 in the vicinity of the terminating end of the tapered shape hole part 12 (in the vicinity of the boundary 15 between the tapered shape hole part 12 and the cylindrical shape hole part 13). A tapered shape via hole is formed by the tapered shape hole part 12 and the conductive film 14, and the wiring 21 and the wiring 22 are electrically connected to each other through the via hole (conductive film 14).

The cylindrical shape hole part 13 communicates with the tapered shape hole part 12 on the smaller diameter side of the tapered shape hole part 12, and has the diameter φ₁, which is smaller than the diameter φ₂ of the tapered shape hole part 12, in a location in which the wiring 22 formed on the smaller diameter side of the tapered shape hole part 12 is connected to the conductive film 14. The cylindrical shape hole part 13 is formed by partially cutting the wall surface 12a on the smaller diameter side of the tapered shape hole part 12 together with the conductive film 14. That is, the superfluous part of the conductive film 14 (that is, stub) other than parts, which are desired to connect the wiring 21 and the wiring 22, is removed in accordance with the formation of the cylindrical shape hole part 13.

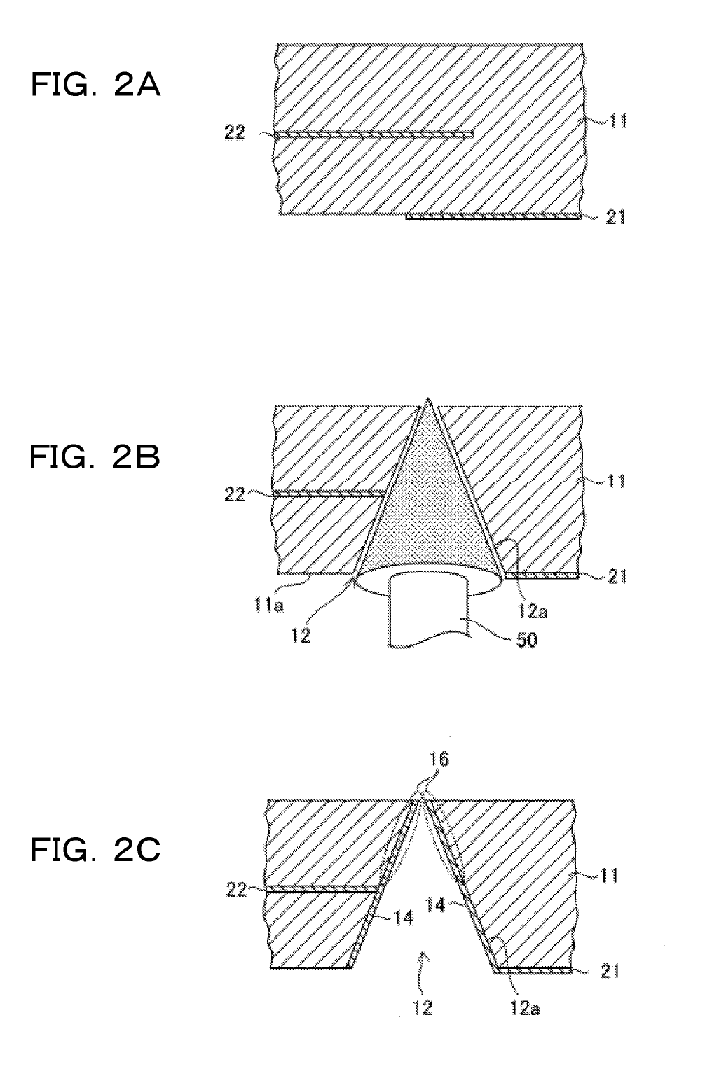

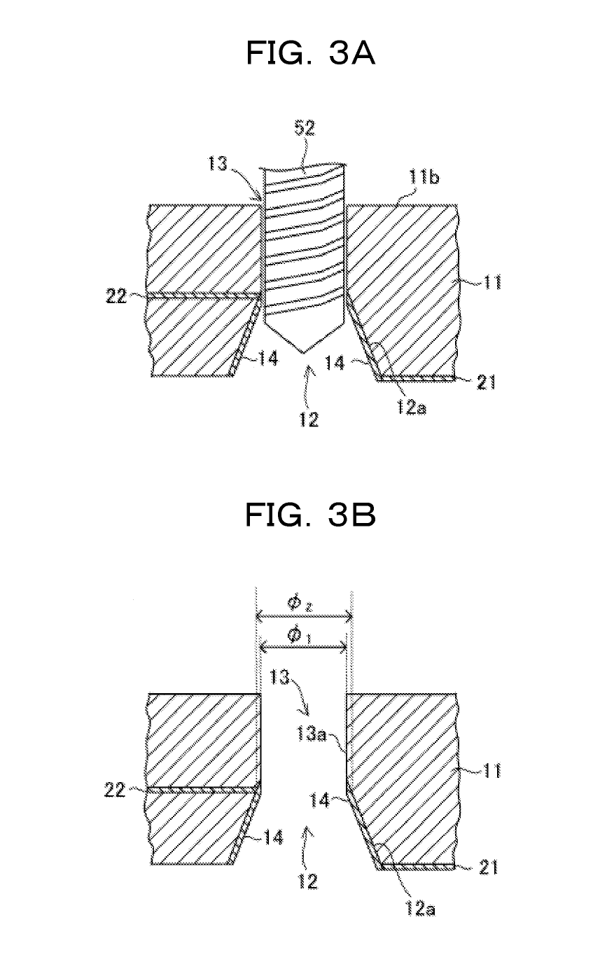

Hereinafter, a method of manufacturing the print substrate 10 will be described. FIGS. 2A to 2C and FIGS. 3A and 3B are cross-sectional diagram respectively illustrating a method of manufacturing the print substrate 10 according to the embodiment of the disclosed technology.

First, as illustrated in FIG. 2A, the base 11, which includes the wiring 21 and the wiring 22 which are formed on wiring layers different from each other, is prepared.

Subsequently, as illustrated in FIG. 2B, when the base 11 is cut from the side of the bottom surface 11a using a coin shape drill 50, the tapered shape hole part 12, which has a cone shape or a truncated cone shape, is formed in the prescribed location of the base 11. A part of the wiring 21 and the wiring 22 may be cut together with the base 11. The wiring 21 and the wiring 22 reach the wall surface 12a of the tapered shape hole part 12. Meanwhile, in an example illustrated in FIG. 2B, the tapered shape hole part 12 passes through the base 11. However, the end of the tapered shape hole part 12 on the smaller diameter side may be terminated inside the base 11.

Subsequently, as illustrated in FIG. 2C, the conductive film 14, which is formed of, for example, an electric conductor such as copper, is formed on the wall surface 12a of the tapered shape hole part 12 using a well-known plating technology. The wiring 21 and the wiring 22 are respectively connected to the conductive film 14. That is, the wiring 21 and the wiring 22 electrically connected with each other through the conductive film 14. A stub 16, which is superfluous part of the conductive film 14 may be formed above the wiring 22 (on the smaller diameter side of the tapered shape hole part 12).

Subsequently, as illustrated in FIG. 3A, the wall surface 12a on the smaller diameter side of the tapered shape hole part 12 is partially cut together with the conductive film 14 (stub 16) using the cylindrical drill 52 which is attached to a machine tool which is not illustrated in the drawing. The center of the shaft of the drill 52 is aligned to the center of the tapered shape hole part 12, and is inserted into the base 11 from, for example, the side of the upper surface 11b of the base 11 (the smaller diameter side of the tapered shape hole part 12). The movement stroke of the drill 52 is controlled in a stroke direction such that at least tip part thereof reaches the tapered shape hole part 12. The drill 52 is inserted into the tapered shape hole part 12 while cutting the wall surface 12a on the smaller diameter side of the tapered shape hole part 12.

The diameter of the drill 52 is smaller than the diameter φ₂ of the tapered shape hole part 12 (refer to FIG. 3B) in a location in which the wiring 22 formed on the smaller diameter side layer of the tapered shape hole part 12 is connected to the conductive film 14. Accordingly, a part, in which the diameter of the tapered shape hole part 12 is smaller than φ₂, of the wall surface 12a of the tapered shape hole part 12 is cut together with the conductive film 14, which covers the part, and then removed. In contrast, since a part of the wall surface 12a of the tapered shape hole part 12, in which the diameter of the tapered shape hole part 12 is equal to or larger than φ₂, and the conductive film 14, which covers the part of the wall surface 12a, do not come into contact with the drill 52, the part and the conductive film 14 remain while not being cut. Since the diameter of the tapered shape hole part 12 is equal to or larger than φ₂ in the depth location of the wiring layer in which the wiring 21 and the wiring 22 are formed, the wiring 21 and the wiring 22 are not damaged in the cutting process. It is similar to the conductive film 14 between the wiring 21 and the wiring 22.

As illustrated in FIG. 3B, the stub 16 (refer to FIG. 2C) is removed through the cutting using the drill 52, and the cylindrical shape hole part 13 which communicates with the tapered shape hole part 12 is formed. The base 11, which is the insulator, is exposed in the wall surface 13a of the cylindrical shape hole part 13. The cylindrical shape hole part 13 has a diameter φ₁ which is smaller than the diameter φ₂ of the tapered shape hole part 12 in a location in which the wiring 22 formed on the smaller diameter side layer of the tapered shape hole part 12 is connected to the conductive film 14. When the difference between the diameter φ₁ and the diameter φ₂ decreases, it is possible to approximately completely remove the stub 16 (refer to FIG. 2C) without damaging the wirings 21 and 22 and the conductive film 14 which connects the wirings 21 and 22.

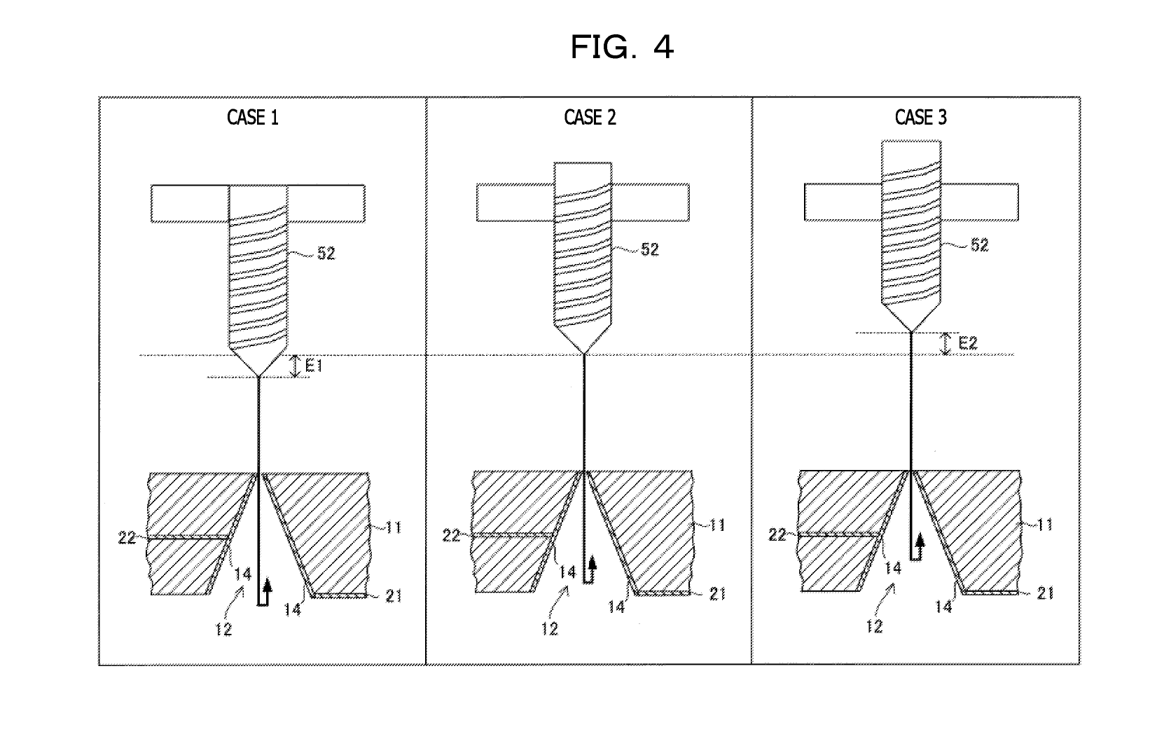

FIG. 4 is a diagram illustrating three cases in which the attachment states of the drill 52, used to form the cylindrical shape hole part 13 with regard to the machine tool in a stroke direction are different from each other. Case 1 indicates when the attachment location of the drill 52 is deviated by distance E1 from a standard location to the downward side of the stroke direction (depth direction of the base 11). Case 2 indicates when the drill 52 is attached to the standard location. Case 3 indicates when the attachment location of the drill 52 is deviated by distance E2 from the standard location to the upward side of the stroke direction. Meanwhile, it is assumed that the movement stroke of the drill 52 in the stroke direction when the base 11 is cut is fixed.

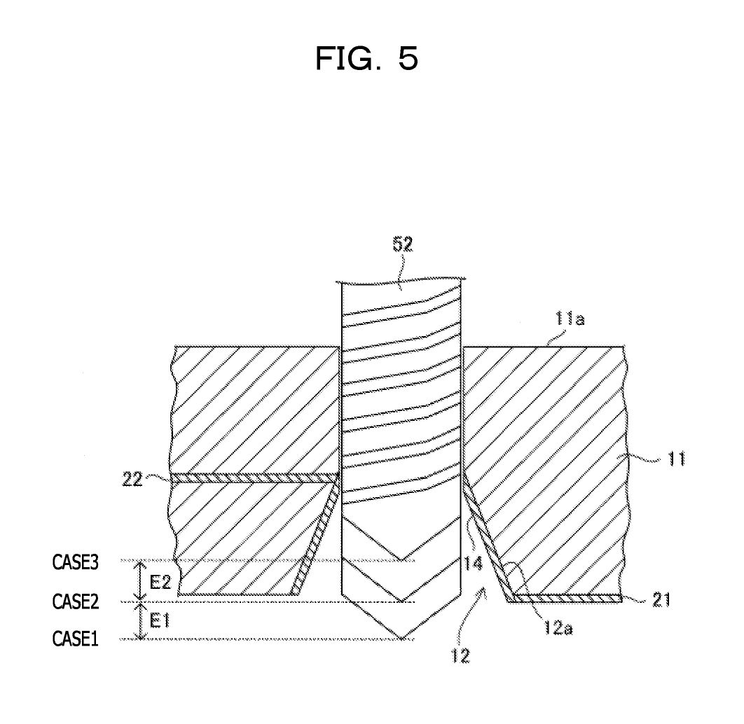

FIG. 5 is a diagram illustrating the insertion depths of the drill 52, which correspond to cases 1 to 3 illustrated in FIG. 4, in the base 11. In cases 1 to 3 illustrated in FIG. 4, the attachment locations of the drill 52 are different from each other in the stroke direction, and thus the insertion depths of the drill 52 in the base 11 are different in the respective cases as illustrated in FIG. 5. That is, the insertion depth of the drill 52 in the base 11 is the deepest in case 1, and the insertion depth of the drill 52 in the base 11 is the most shallow in case 3.

However, the part of the wall surface 12a of the tapered shape hole part 12, in which the diameter of the tapered shape hole part 12 is larger than the diameter of the drill 52, and the conductive film 14, which covers the part of the wall surface 12a, do not come into contact with the drill 52 in any case. Accordingly, when the attachment location of the drill 52 with regard to the machine tool changes, the cut part does not change, and thus it is possible to usually acquire a fixed finishing state. That is, in the print substrate 10 and the method of manufacturing the print substrate 10 according to the embodiment, it is possible to approximately completely remove the stub without damaging the wirings 21 and 22 and the conductive film 14, which connects the wirings 21 and 22, regardless of the location accuracy of the drill 52 in the stroke direction.

In the print substrate 10 and the method of manufacturing the print substrate 10 according to the embodiment, it is available regardless of the locations of the wiring 21 and the wiring 22 in the thickness direction of the print substrate 10.

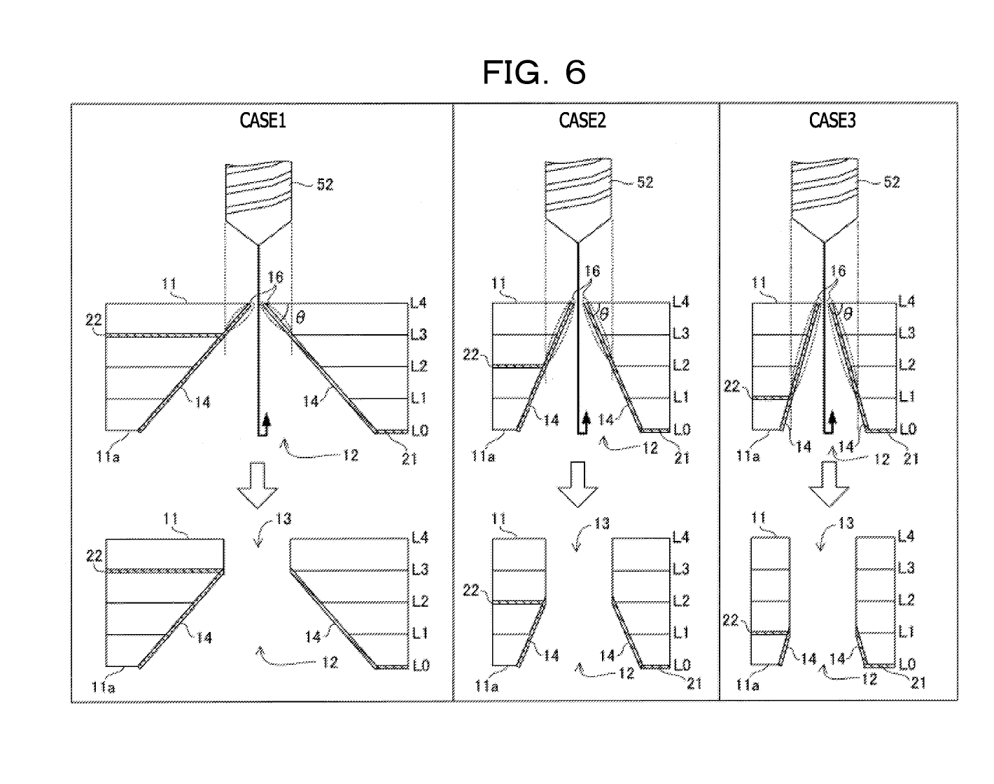

FIG. 6 is a diagram illustrating a method of removing the stub 16 using the drill 52, which has the same diameter, in three cases in which the locations of the wirings 22, formed on the smaller diameter side of the tapered shape hole part 12, in the depth direction of the base 11 are different from each other. Case 1 indicates that the wiring 22 is formed on a wiring layer L3. Case 2 indicates that the wiring 22 is formed on a wiring layer L2. Case 3 indicates that the wiring 22 is formed on a wiring layer L1. In all the cases, the wiring 21 on the larger diameter side of the tapered shape hole part 12 is formed on a wiring layer LO (the bottom surface 11a of the base 11).

When the diameter of the drill 52, which is used in each case, is the same, the taper angle θ (opening diameter) of the tapered shape hole part 12 is appropriately adjusted as illustrated in FIG. 6, and thus it is possible to approximately completely remove the stub without damaging the wirings 21 and 22 and the conductive film 14 which connects the wirings 21 and 22. That is, as the distance between the wiring 21 and the wiring 22 increases, the taper angle θ (opening diameter) of the tapered shape hole part 12 may decrease. In all of the cases, the taper angle θ (opening diameter) is adjusted such that the diameter of the tapered shape hole part 12 in a location in which the wiring 22 is connected to the conductive film 14 becomes larger than the diameter of the drill 52. That is, in the print substrate 10, plural tapered shape hole parts 12, which have respectively different taper angles θ determined according to the locations of the wirings in the thickness direction of the base 11, may be formed.

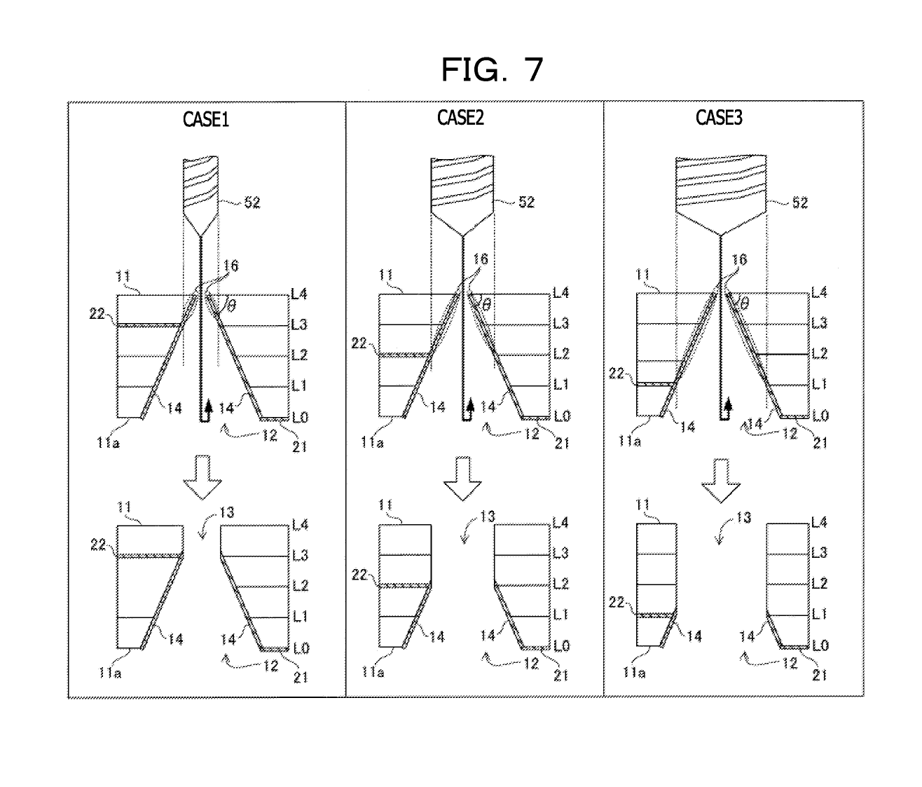

FIG. 7 is a diagram illustrating a method of removing the stub 16 when the taper angle θ (opening diameter) of the tapered shape hole part 12 is the same in three cases in which the locations of the wirings 22, formed on the smaller diameter side of the tapered shape hole part 12, in the thickness direction of the base 11 are different from each other. Case 1 indicates that the wiring 22 is formed on the wiring layer L3. Case 2 indicates that the wiring 22 is formed on the wiring layer L2. Case 3 indicates that the wiring 22 is formed on the wiring layer L1. In all of the cases, the wiring 21 on the larger diameter side of the tapered shape hole part 12 is formed on the wiring layer L0 (the bottom surface 11a of the base 11).

When the taper angle θ (opening diameter) of the tapered shape hole part 12 is the same in each case and the diameter of the drill 52 to be used is appropriately adjusted as illustrated in FIG. 7, it is possible to approximately completely remove the stub without damaging the wirings 21 and 22 and the conductive film 14 which connects the wirings 21 and 22. That is, as the distance between the wiring 21 and the wiring 22 increases, the diameter of the drill 52 may decrease. In all of the cases, the drill 52, which has a smaller diameter than the tapered shape hole part 12 in a location in which the wiring 22 is connected to the conductive film 14, is used. That is, in the print substrate 10, plural cylindrical shape hole parts 13, which have respectively different diameters determined according to the locations of the wirings in the thickness direction of the base 11, may be formed.

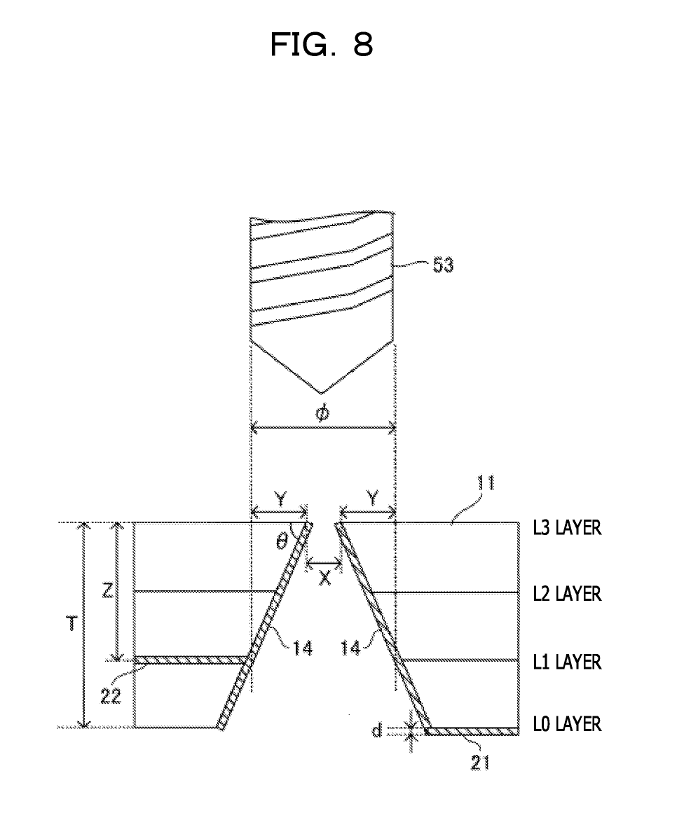

Here, as illustrated in FIG. 8, it is assumed that the diameter of the drill 52 to remove the stub is φ, the thickness of the base 11 is T, a cut distance through the drill 52 is Z, the taper angle of the tapered shape hole part 12 is θ, the thickness of the wiring 21 and the wiring 22 is d, the total number of wiring layers is n (in an example illustrated in FIG. 8, n=4). In addition, it is assumed that the number of layers of the plural wiring layers from the outermost layer (in the example illustrated in FIG. 8, the wiring layer L3) of the smaller diameter side of the tapered shape hole part 12 to the wiring layer (in the example illustrated in FIG. 8, the wiring layer L1) on which the wiring 22 is formed is m (in the example illustrated in FIG. 8, m=2), and the opening diameter of the smaller diameter side of the tapered shape hole part 12 is X.

In this case, it is possible to express the cut distance Z using Equation (1) below.

Z=(T/(n−1))×m−d (1)

In addition, it is possible to express the diameter φ of the drill 52 using Equation (2) below.

φ=X+2Y=X+2×(Z·cosθ/sinθ) (2)

An example of calculating the diameter φ of the drill 52 using Equations (1) and (2) will be expressed below. Here, as an example, a case in which T=3000 μm, n=4 layers, m=2 layers, d=35 μm, X=400 μm, and θ=45° will be described. In this case, the cut distance Z is calculated as below using Equation (1).

Z=(3000 μm/(4−1))×2−35 μm=1965 μm

In addition, the diameter φ of the drill 52 is calculated as below using Equation (2).

φ=400 μm+2×(1965 μm·cos45°/sin45°)=4330 μm

In contrast, when the diameter φ of the drill 52 is settled, it is possible to calculate the taper angle θ of the tapered shape hole part 12 based on Equation (3).

tanθ=2×Z/((φ−x) (3)

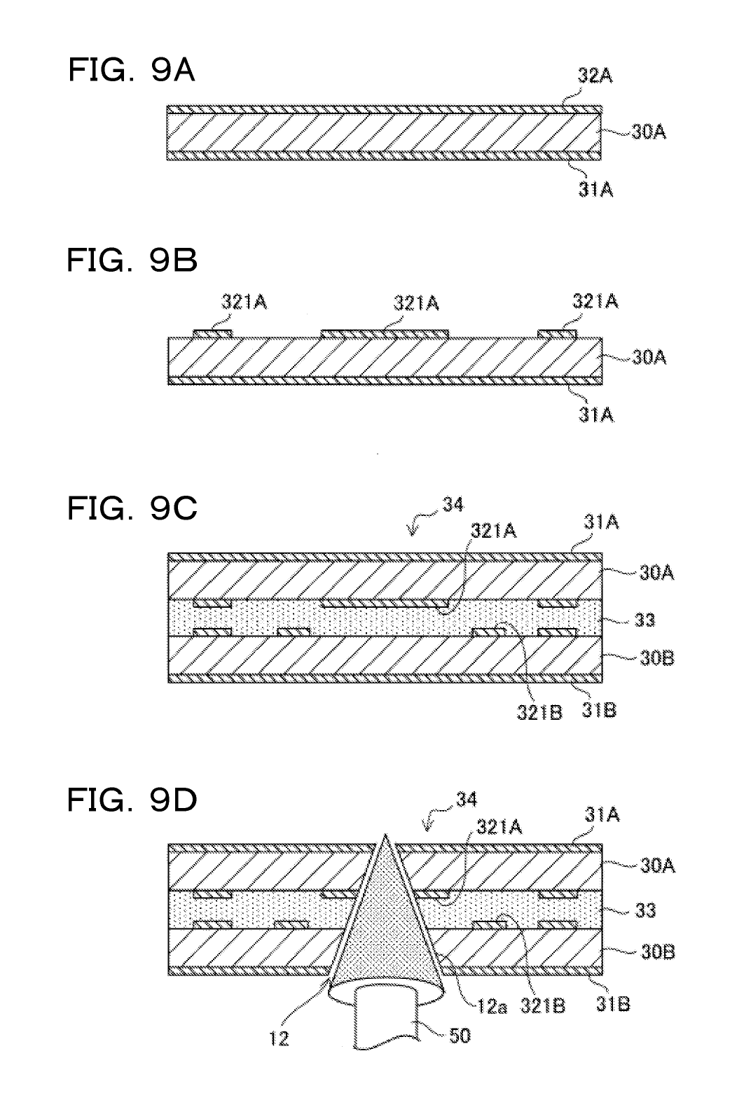

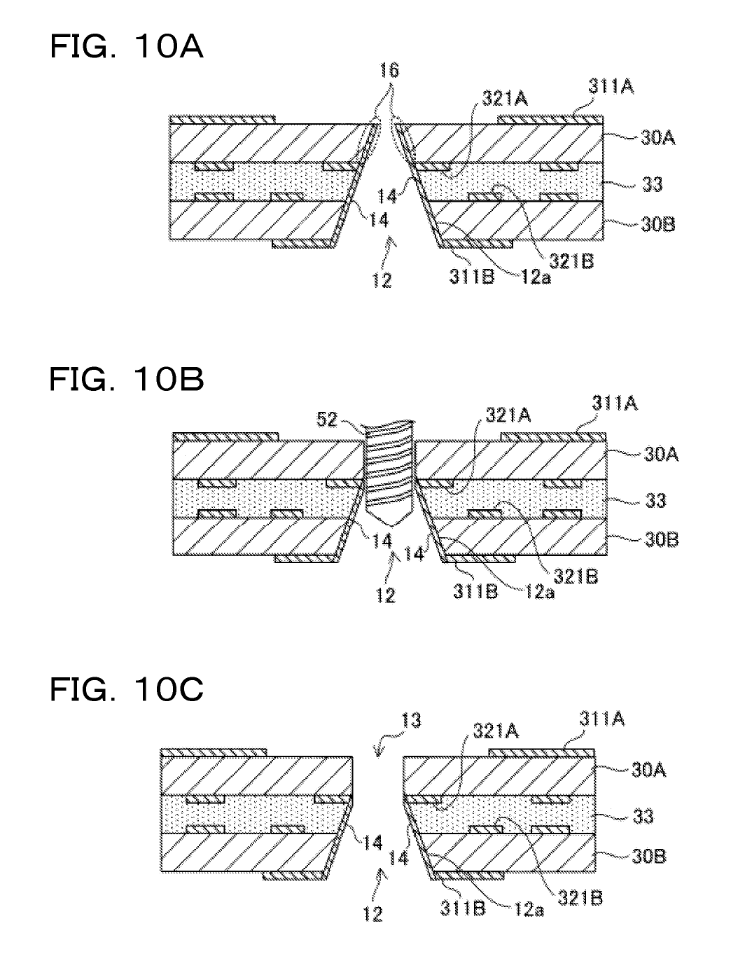

FIGS. 9A to 9D and FIGS. 10A to 10C are cross-sectional diagrams illustrating the method of manufacturing the print substrate according to the embodiment of the disclosed technology.

Initially, as illustrated in FIG. 9A, a base 30A, on which copper foils 31A and 32A are formed on both surfaces thereof, is prepared. Subsequently, as illustrated in FIG. 9B, a wiring 321A is formed by performing desired patterning on the copper foil 32A which is arranged on the inner layer side of the print substrate using a well-known photolithography technology. Plural bases (here, two), in which a wiring pattern is formed, are manufactured by repeatedly performing the same process.

Subsequently, as illustrated in FIG. 9C, two bases 30A and 30B are bonded together such that a surface on which the wiring 321A is formed faces a surface on which a wiring 321B is formed. The two bases 30A and 30B are bonded by interposing an adhesion layer 33 therebetween. Therefore, a laminated substrate 34 is formed. It is possible to suitably use, for example, prepreg as the construction material of the adhesion layer 33.

Subsequently, as illustrated in FIG. 9D, the tapered shape hole part 12 is formed in the prescribed location of the laminated substrate 34 using the coin shape drill 50, and the wiring 321A is exposed in the wall surface 12a of the tapered shape hole part 12. In an example illustrated in FIG. 9D, the drill 50 is inserted from the side of the base 30B.

Subsequently, as illustrated in FIG. 10A, the conductive film 14, which is formed of, for example, an electric conductor such as copper, is formed on the wall surface 12a of the tapered shape hole part 12 using the well-known plating technology. Thereafter, the wiring 311A and the wiring 311B are formed by performing desired patterning on the copper foils 31A and 31B on the outer layer side of the bases 30A and 30B using the well-known photolithography technology. The wiring 311B on the outer layer side is electrically connected to the wiring 321A on the inner layer side through the conductive film 14. The stub 16, which is the superfluous part of the conductive film 14, is formed on the smaller diameter side of the tapered shape hole part 12.

Subsequently, as illustrated in FIG. 10B, the wall surface of the tapered shape hole part 12 on the smaller diameter side is partially cut together with the conductive film 14 (stub 16) using the cylindrical drill 52. The center of the shaft of the drill 52 is aligned to the center of the tapered shape hole part 12. The drill 52 has a smaller diameter than the tapered shape hole part 12 in a location in which the wiring 321A allocated on the smaller diameter side of the tapered shape hole part 12 is connected to the conductive film 14. Therefore, as illustrated in FIG. 10C, the cylindrical shape hole part 13 which communicates with the tapered shape hole part 12 is formed, and the stub 16 is removed without damaging the wirings 321A and 311B and the conductive film 14 which connects the wirings 321A and 311B.

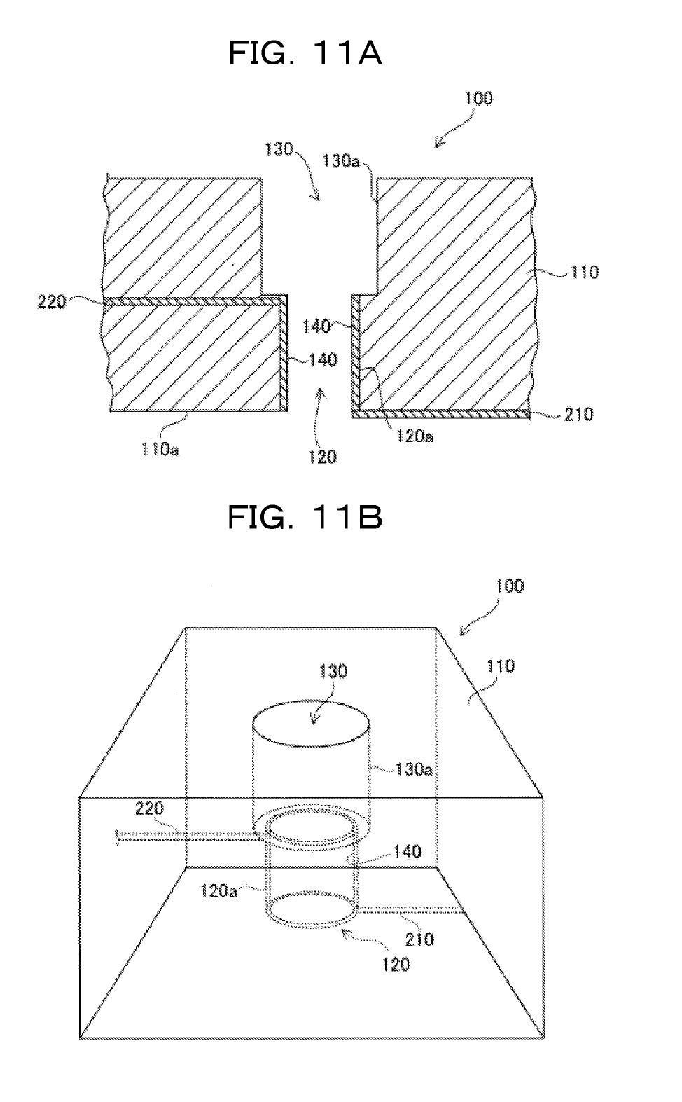

FIG. 11A is a cross-sectional diagram illustrating the partial configuration of the print substrate 100 according to the comparative example. FIG. 11B is a perspective view illustrating the partial configuration of the print substrate 100 according to the comparative example.

The print substrate 100 has a multilayer wiring structure which includes wiring layers on the surface and inside of the base 110. A wiring 210 is formed on the bottom surface 110a of the base 110, and a wiring 220 is formed inside the base 110.

The print substrate 100 includes a first cylindrical shape hole part 120 that forms a via hole, and a second cylindrical shape hole part 130 that communicates with the first cylindrical shape hole part 120. The diameter of the second cylindrical shape hole part 130 is larger than the diameter of the first cylindrical shape hole part 120. A through hole, which passes through the base 110, is formed by the first cylindrical shape hole part 120 and the second cylindrical shape hole part 130.

The wall surface 120a of the first cylindrical shape hole part 120 is covered by the conductive film 140 which is formed of an electric conductor such as copper. The conductive film is not formed on the wall surface 130a of the second cylindrical shape hole part 130, and the base 110, which is an insulator, is exposed. The wiring 210 and the wiring 220 are respectively connected to the conductive film 140. A cylindrical via hole is formed by the first cylindrical shape hole part 120 and the conductive film 140, and the wiring 210 and the wiring 220 are electrically connected to each other through the via hole (conductive film 140).

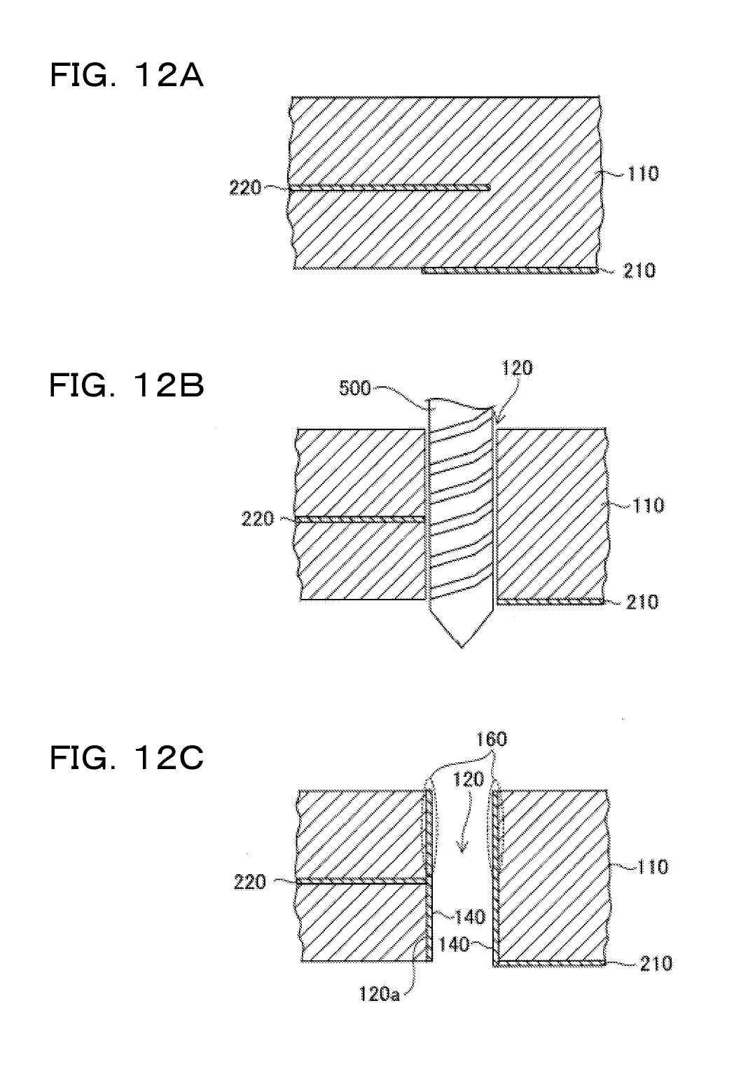

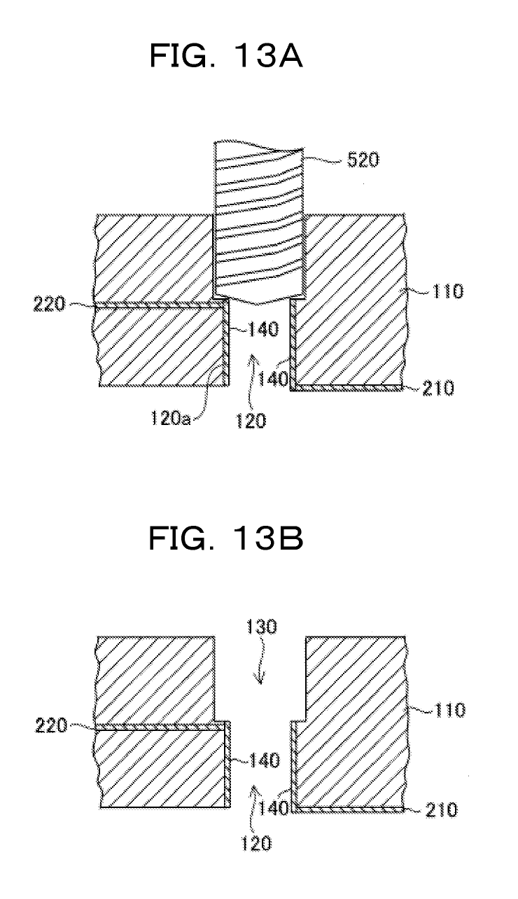

Hereinafter, a method of manufacturing the print substrate 100 according to the comparative example will be described. FIGS. 12A to 12C and 13A to 13B are cross-sectional diagrams respectively illustrating the method of manufacturing the print substrate 100 according to the comparative example.

First, as illustrated in FIG. 12A, the base 110, which includes the wiring 210 and the wiring 220 which are formed on wiring layers different from each other, is prepared.

Subsequently, as illustrated in FIG. 12B, a first cylindrical shape hole part 120, which passes through the base 110, is formed in the prescribed location of the base 110 using a drill 500.

Subsequently, as illustrated in FIG. 12C, a for example, the conductive film 140, which is formed of an electric conductor such as copper, is formed on the wall surface 120a of the first cylindrical shape hole part 120 using a well-known plating technology. The wiring 210 and the wiring 220 are respectively connected to the conductive film 140. A stub 160, which is superfluous part of the conductive film 140, is formed above the wiring 220.

Subsequently, as illustrated in FIG. 13A, the wall surface 120a of the first cylindrical shape hole part 120 on upward side is partially cut together with the conductive film 140 (stub 160) using a cylindrical drill 520, which has a diameter larger than the diameter of the first cylindrical shape hole part 120. The center of the drill 520 is aligned to the center of the first cylindrical shape hole part 120. When the cutting is performed using the drill 520, the stub 160 is removed, and a second cylindrical shape hole part 130, which communicates with the first cylindrical shape hole part 120, is formed as illustrated in FIG. 13B.

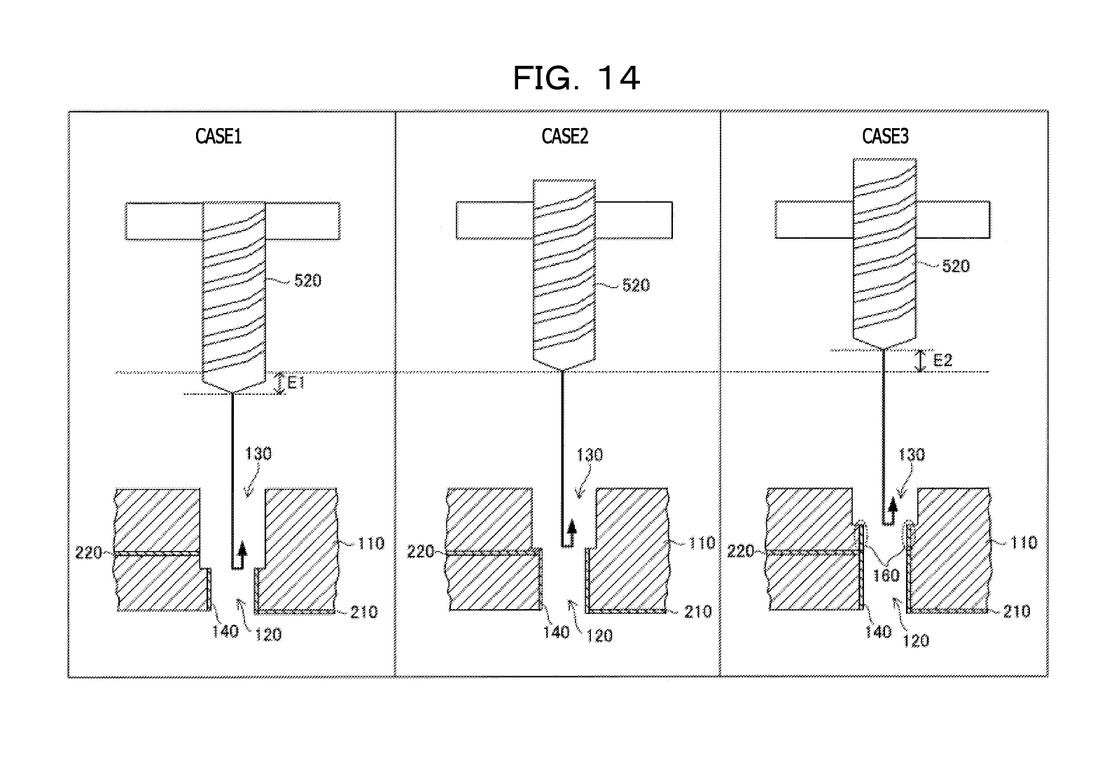

FIG. 14 is a diagram illustrating three cases in which the attachment states of the drill 520, used to manufacture the second cylindrical shape hole part 130 in the print substrate 100 according to the comparative example, with regard to the machine tool in the stroke direction are different from each other. Case 1 indicates that the attachment location of the drill 520 is deviated by distance E1 on the downward side of the stroke direction (the depth direction of the base 110) with regard to a standard location. Case 2 indicates that the drill 520 is attached to the standard location. Case 3 indicates that the attachment location of the drill 520 is deviated by distance E2 on the upward side of the stroke direction with regard to the standard location. Meanwhile, it is assumed that the movement stroke of the drill 520 in the stroke direction when the base 110 is cut is fixed.

In case 2 in which the drill 520 is attached to the standard location, it is possible to approximately completely remove the stub without damaging the wirings 210 and 220 and the conductive film 140 which connects the wirings 201 and 220. In contrast, in case 1 in which the attachment location of the drill 520 is deviated on the downward side of the stroke direction with regard to the standard location, the insertion depth of the drill 520 with regard to the base 110 is deep in comparison to case 2. Accordingly, as illustrated in FIG. 14, there is a problem in that a part of the conductive film 140, which is connected to the wiring 210 and the wiring 220, and a part of the wiring 220 are cut, and thus the wiring 210 and the wiring 220 are disconnected. In contrast, in case 3 in which the attachment location of the drill 520 is deviated on the upward side of the stroke direction with regard to the standard location, the insertion depth of the drill 520 with regard to the base 110 is shallow in comparison to case 2. Accordingly, as illustrated in FIG. 14, it is difficult to completely remove the stub 160.

As above, in the manufacturing method according to the comparative example, it is difficult to completely remove the stub without damaging the conductive film, which connects between the wirings, due to the variation in the attachment states of the drill 520 with regard to the machine tool.

In contrast, in the print substrate 10 and the manufacturing method according to the embodiment of the disclosed technology, when the attachment location of the drill 52, which is used to remove the stub, changes with regard to the machine tool, it is possible to usually acquire a fixed finishing state without changing the cutting part. That is, it is possible to approximately completely remove the stub without damaging the conductive film, which connects between the wirings, regardless of the location accuracy of the drill 52 in the stroke direction.

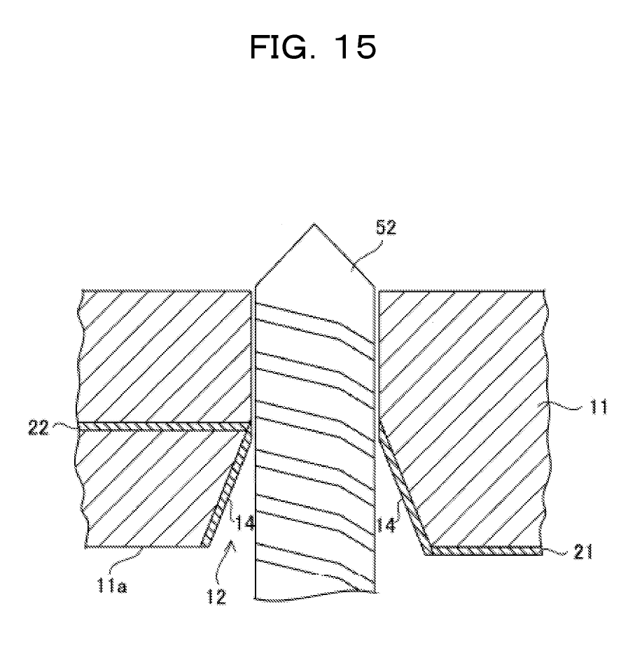

In addition, in the print substrate 10 and the manufacturing method thereof according to the disclosed technology, it is possible to insert the drill 52, which is used to remove the stub, from either the upper surface or the bottom surface of the base 11. That is, the example illustrated in FIG. 3A illustrates a case in which the drill 52 is inserted into the base 11 from the side of the upper surface 11b (the smaller diameter side of the tapered shape hole part 12) of the base 11. However, as illustrated in FIG. 15, it is possible to insert the drill 52 into the base 11 from the side of the bottom surface 11a of the base 11 (the larger diameter side of the tapered shape hole part 12). As above, in the print substrate 10 and the manufacturing method thereof according to the disclosed technology, the insertion direction of the drill 52, which is used to remove the stub, is not limited, and thus it is possible to improve the flexibility of a manufacturing process.

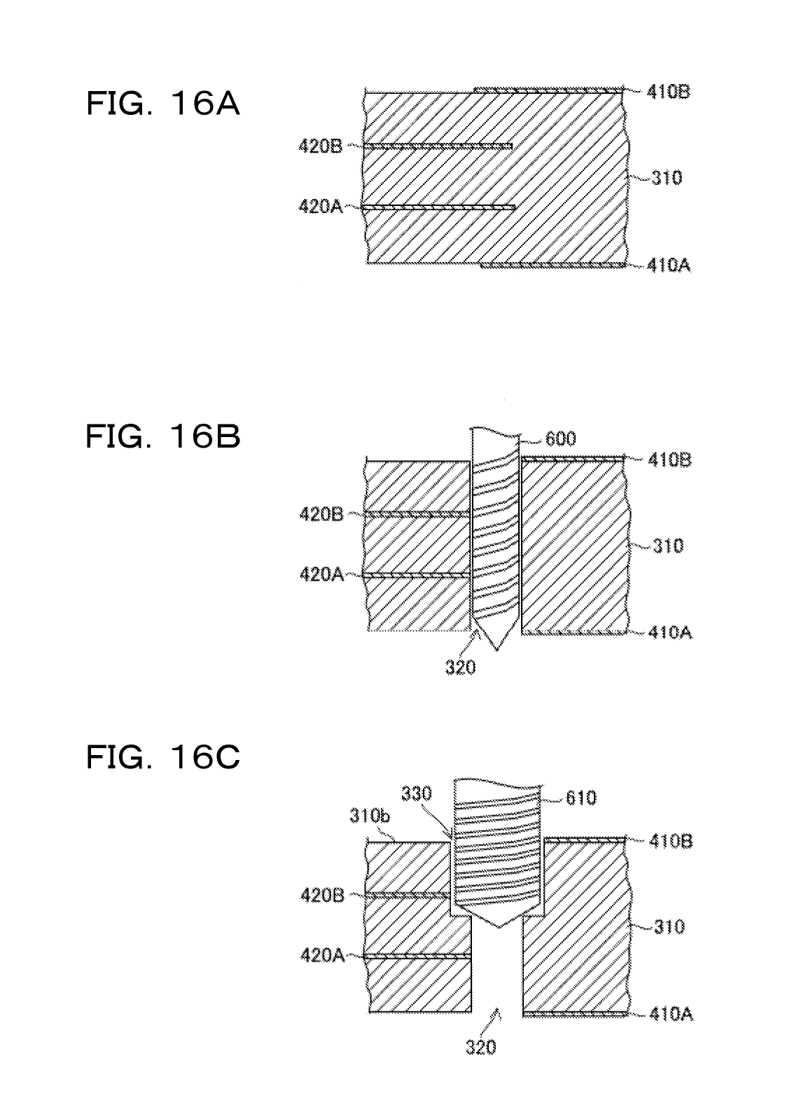

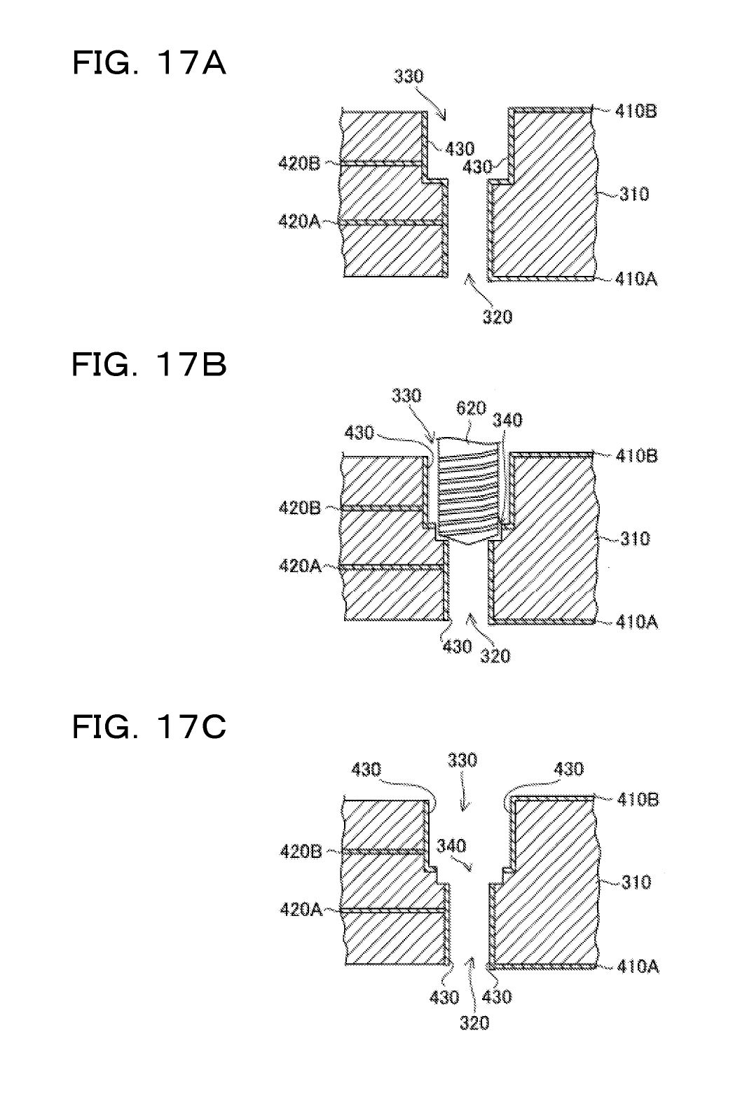

Hereinafter, a print substrate and a manufacturing method thereof according to another comparative example will be described with reference to FIGS. 16A to 16C and 17A to 17C.

First, as illustrated in FIG. 16A, a base 310, which includes wirings 410A, 420A, 410B, and 420B which are formed on wiring layers different from each other, is prepared.

Subsequently, as illustrated in FIG. 16B, a through hole 320 is formed in the base 310 using a first drill 600.

Subsequently, as illustrated in FIG. 16C, when the side of the upper surface 310b of the base 310 is cut using a second drill 610, which has a diameter larger than the diameter of the first drill 600, a first cut hole 330, which has a diameter larger than the diameter of the through hole 320, is formed. The bottom surface of the first cut hole 330 is located between the wirings 420B and 420A.

Subsequently, as illustrated in FIG. 17A, a conductive film 430 is formed to cover the wall surfaces of the through hole 320 and the first cut hole 330. The wirings 410A, 420A, 420B, and 410B are electrically connected to each other through the conductive film 430.

Subsequently, as illustrated in FIG. 17B, the bottom surface of the first cut hole 330 is cut using a third drill 620 which has a diameter larger than the diameter of the first drill 600 and smaller than the diameter of the second drill 610. Therefore, a second cut hole 340, which has a diameter larger than the diameter of the through hole 320 and smaller than the diameter of the first cut hole 330, is formed. As illustrated in FIG. 17C, the bottom surface of the second cut hole 340 is located between the wiring 420B and the wiring 420A. In accordance with the formation of the second cut hole 340, the conductive film 430 is disconnected inside the base 310. That is, a pair of the wiring 410A and the wiring 420A is divided from a pair of the wiring 410B and the wiring 420B by the second cut hole 340.

As described above, the print substrate and the manufacturing method thereof according to another comparative example includes four processes below. (1) A process to form the through hole 320 (refer to FIG. 16B), (2) a process to form the first cut hole 330 (refer to FIG. 16C), (3) a process to form the conductive film 430 (refer to FIG. 17A), and (4) a process to form the second cut hole 340. In contrast, the above-described method of manufacturing the print substrate 10 according to the embodiment of the disclosed technology is sufficient with three processes below. (1) A process to form the tapered shape hole part 12 (refer to FIG. 2B), (2) a process to form the conductive film 14 (refer to FIG. 2C), and (3) a process to form the cylindrical shape hole part 13 (refer to FIG. 3A).

In addition, in the print substrate and the manufacturing method thereof according to another comparative example, three drills 600, 610, and 620, which have diameters different from each other, are desired. In contrast, in the method of manufacturing the print substrate according to the embodiment of the disclosed technology, the drills, which are used, are sufficient with two types, that is, the coin shape drill 50 and the cylindrical drill 52.

As above, in the method of manufacturing the print substrate 10 according to the embodiment of the disclosed technology, it is possible to reduce the number of processes to manufacture one via hole and man hours, which are desired to change the drills, compared to the print substrate and the manufacturing method thereof according to another comparative example. Usually, plural via holes are formed in the print substrate, with the result that at least one of the number of processes to manufacture one via hole and at least one the man hours, which are desired to change the drills, are respectively reduced, and thus it is possible to remarkably reduce the total man hours which are desired to manufacture the print substrate.

In addition, in the print substrate according to another comparative example, a step is formed between the wall surface of the through hole 320 and the wall surface of the first cut hole 330. It is difficult to form the conductive film 430 with uniform thickness in the stepped part, and thus there is a problem in that the conductive film 430 is disconnected at the stepped part. In contrast, in the print substrate according to the embodiment of the disclosed technology, the conductive film 14 is formed to have the wall surface 12a of the tapered shape hole part 12, which has no step (refer to FIG. 2C), with the result that it is easy to for the conductive film 14 with uniform thickness, and thus there are few risks in which the conductive film 14 is disconnected.

In addition, in the print substrate and the manufacturing method thereof according to another comparative example, it is desired to respectively locate the bottom surface of the first cut hole 330 and the bottom surface of the second cut hole 340 between the wiring 420A and the wiring 420B. Accordingly, it is desired to ensure the location accuracy in the stroke direction of the second drill 610 and the third drill 620. In contrast, in the method of manufacturing the print substrate according to the embodiment of the disclosed technology, the location accuracy in the stroke direction of the drills 50 and 52 is not desired, and thus it is possible to realize stabilization of quality.

### Second Embodiment

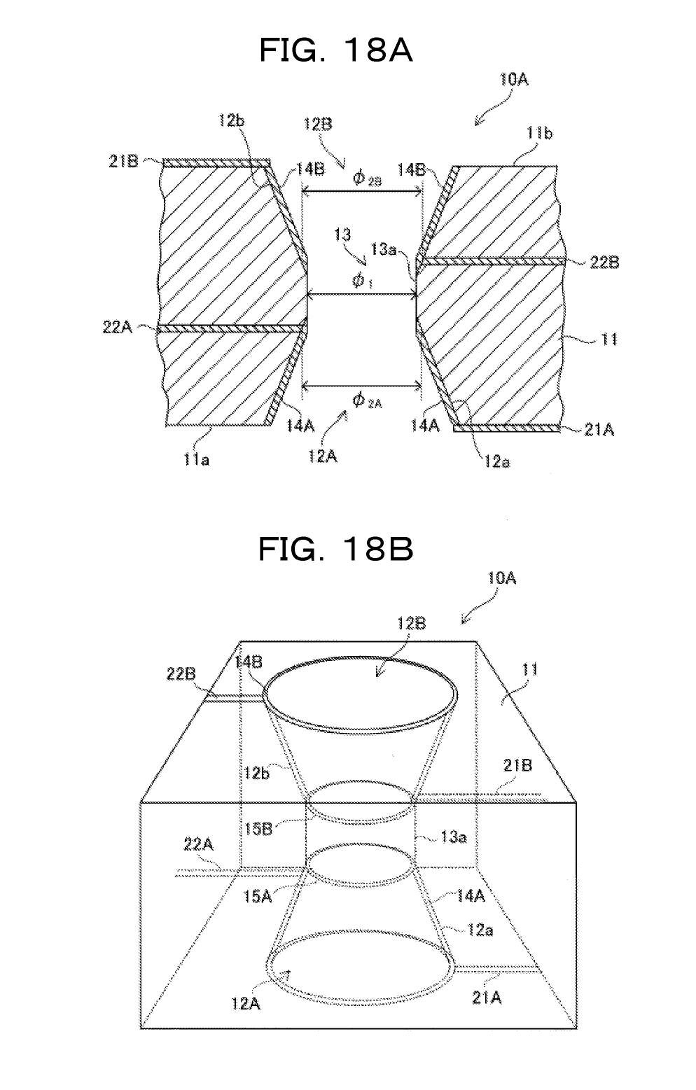

FIG. 18A is a cross-sectional diagram illustrating the partial configuration of a print substrate 10A according to a second embodiment of the disclosed technology. FIG. 18B is a perspective view illustrating the partial configuration of the print substrate 10A.

The print substrate 10A has a multilayer wiring structure which includes plural wiring layers. In the embodiment, the print substrate 10A includes wirings 21A, 22A, 21B, and 22B which are formed wiring layers different from each other. The wiring 21A is formed on the bottom surface 11a of the base 11, and the wiring 22A is formed inside the base 11. In addition, the wiring 21B is formed on the upper surface 11b of the base 11, and the wiring 22B is formed inside the base 11.

It is possible to use a glass epoxy substrate, acquired in such a way that a laminated body in which cloth made of glass fiber is laminated is impregnated with an epoxy resin, as an example of the base 11. Meanwhile, the material of the base 11 is not particularly limited, and it is possible to use a well-known material of a paper phenol substrate, a paper epoxy substrate, a glass composite substrate, or the like.

The print substrate 10A includes tapered shape hole parts 12A and 12B that are respectively formed on the bottom surface 11a and the upper surface 11b of the base 11 and that have diameters which continuously change along the depth direction of the base 11 (thickness direction). The tapered shape hole part 12A has a diameter which continuously changes toward the inside the base 11 from the bottom surface 11a of the base 11. The tapered shape hole part 12B has a diameter which continuously changes toward the inside the base 11 from the upper surface 11b of the base 11. As illustrated in FIG. 16B, the tapered shape hole parts 12A and 12B respectively have a truncated cone shape, and are formed to be concentric with each other. The tapered shape hole parts 12A and 12B form a via hole.

The print substrate 10A includes a cylindrical shape hole part 13 that communicates with the tapered shape hole parts 12A and 12B therebetween. The cylindrical shape hole part 13 has a diameter φ₁ which has the same size as the diameters of the tapered shape hole parts 12A and 12B at the small diameter-side ends thereof. In addition, the cylindrical shape hole part 13 is formed to be concentric with the tapered shape hole parts 12A and 12B. A through hole, which passes through the base 11, is formed by the tapered shape hole parts 12A and 12B and the cylindrical shape hole part 13.

The wall surface 12a of the tapered shape hole part 12A is covered by a conductive film 14A which is formed of an electric conductor such as copper. In the same manner, the wall surface 12b of the tapered shape hole part 12B is covered by a conductive film 14B which is formed of an electric conductor such as copper. The wall surface 13a of the cylindrical shape hole part 13 is not formed with the conductive film, and the base 11, which is an insulator, is exposed.

The wiring 21A, which is formed on a wiring layer on the larger diameter side of the tapered shape hole part 12A, is connected to the conductive film 14A at the opening end of the tapered shape hole part 12A. The wiring 22A, which is formed on a wiring layer on the smaller diameter side of the tapered shape hole part 12A, is connected to the conductive film 14A in the vicinity of the terminating end of the tapered shape hole part 12A (in the vicinity of the boundary 15A between the tapered shape hole part 12A and the cylindrical shape hole part 13). A tapered shape via hole is formed by the tapered shape hole part 12A and the conductive film 14A, and the wiring 21A and the wiring 22A are electrically connected to each other through the via hole (conductive film 14A).

The wiring 21B, which is formed on a wiring layer on the larger diameter side of the tapered shape hole part 12B, is connected to the conductive film 14B at the opening end of the tapered shape hole part 12B. The wiring 22B, which is formed on a wiring layer on the smaller diameter side of the tapered shape hole part 12B, is connected to the conductive film 14B in the vicinity of the terminating end of the tapered shape hole part 12B (in the vicinity of the boundary 15B between the tapered shape hole part 12B and the cylindrical shape hole part 13). A tapered shape via hole is formed by the tapered shape hole part 12B and the conductive film 14B, and the wiring 21B and the wiring 22B are electrically connected to each other through the via hole (conductive film 14B).

The cylindrical shape hole part 13 is formed to communicate with the tapered shape hole parts 12A and 12B by partially cutting the wall surfaces 12a and 12b of the tapered shape hole parts 12A and 12B on the smaller diameter side thereof together with the conductive films 14A and 14B. The diameter φ₁ of the cylindrical shape hole part 13 is smaller than the diameter φ_{2A} of the tapered shape hole part 12A in a location in which the wiring 22A formed on the wiring layer on the smaller diameter side of the tapered shape hole part 12A is connected to the conductive film 14A.

In addition, the diameter φ₁ of the cylindrical shape hole part 13 is smaller than the diameter φ_{2B} of the tapered shape hole part 12B in a location in which the wiring 22B formed on the wiring layer on the smaller diameter side of the tapered shape hole part 12B is connected to the conductive film 14B.

Accordingly, the superfluous part of the conductive film 14A (that is, stub) other than parts, which are desired to connect the wiring 21A and the wiring 22A, is removed in accordance with the formation of the cylindrical shape hole part 13. In the same manner, the superfluous part of the conductive film 14B (that is, stub) other than parts, which are desired to connect the wiring 21B and the wiring 22B, is removed in accordance with the formation of the cylindrical shape hole part 13.

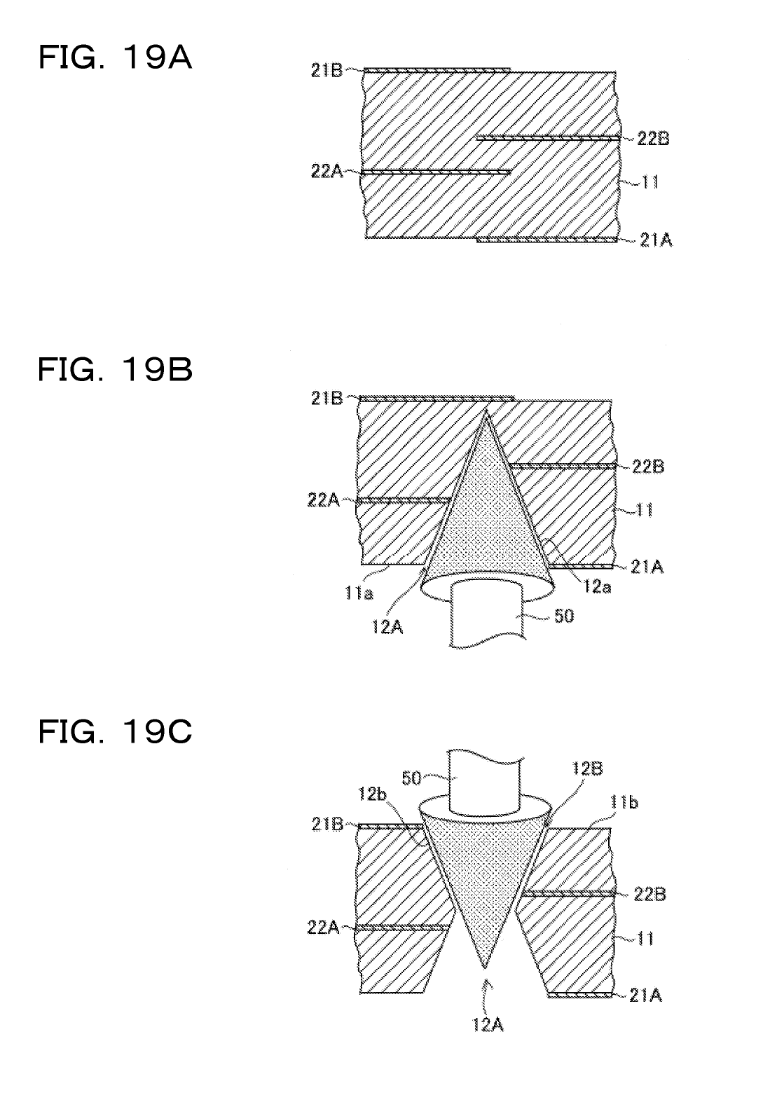

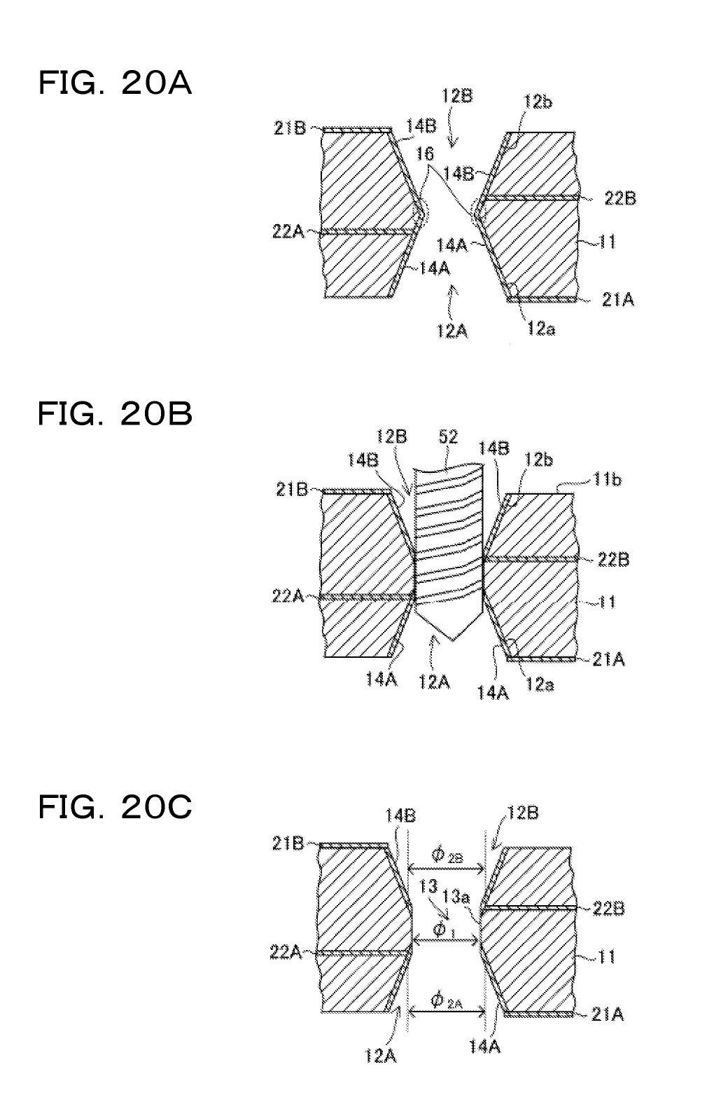

Hereinafter, a method of manufacturing the print substrate 10A according to the second embodiment of the disclosed technology will be described. FIGS. 19A to 19C and 20A to 20C are cross-sectional diagrams respectively illustrating the method of manufacturing the print substrate 10A according to the second embodiment of the disclosed technology.

First, as illustrated in FIG. 19A, a base 11, which includes wirings 21A, 21B, 22A, and 22B which are formed on wiring layers different from each other, is prepared.

Subsequently, as illustrated in FIG. 19B, the tapered shape hole part 12A, which has a cone shape or a truncated cone shape, is formed in the prescribed location of the base 11 by cutting the base 11 from the side of the bottom surface 11a using a coin shape drill 50. Parts of the wirings 21A and 22A may be cut together with the base 11. The wirings 21A and 22A reach the wall surface 12a of the tapered shape hole part 12A.

Subsequently, as illustrated in FIG. 19C, the tapered shape hole part 12B, which has a cone shape or a truncated cone shape, is formed in the prescribed location of the base 11 by cutting the base 11 from the side of the upper surface 11b using the coin shape drill 50. The center of the shaft of the drill 50 is aligned to the center of the tapered shape hole part 12A which is formed in advance. That is, the tapered shape hole part 12B is formed to be concentric with the tapered shape hole part 12A. The tapered shape hole part 12B is formed to communicate with the tapered shape hole part 12A, and a through hole, which passes through the base 11, is formed by the tapered shape hole parts 12A and 12B. Parts of the wiring 21B and the wiring 22B may be cut together with the base 11. The wiring 21B and the wiring 22B reach the wall surface 12b of the tapered shape hole part 12B.

Subsequently, as illustrated in FIG. 20A, the conductive films 14A and 14B, which are formed of electric conductors such as copper, are formed on the wall surfaces 12a and 12b of the tapered shape hole parts 12A and 12B using a well-known plating technology. The wiring 21A and the wiring 22A are respectively connected to the conductive film 14A, and the wiring 21B and the wiring 22B are respectively connected to the conductive film 14B. At this point of time, the conductive film 14A and the conductive film 14B are connected to each other. A stub 16, which is the superfluous part of the conductive films 14A and 14B, is formed between the wiring 22A and the wiring 22B.

Subsequently, as illustrated in FIG. 20B, the wall surfaces 12a and 12b of the tapered shape hole parts 12A and 12B on the smaller diameter side thereof are partially cut together with the conductive films 14A and 14B (stub 16) using a cylindrical drill 52. The center of the shaft of the drill 52 is aligned to the centers of the tapered shape hole parts 12A and 12B. The drill 52 is inserted into the base 11 from, for example, the side of the upper surface 11b of the base 11, and the movement stroke of the drill 52 is controlled in the stroke direction such that at least the tip part of the drill 52 reaches the tapered shape hole part 12A. The drill 52 is inserted into the tapered shape hole parts 12A and 12B while cutting the wall surfaces 12a and 12b of the tapered shape hole parts 12A and 12B on the smaller diameter side.

The diameter of the drill 52 is smaller than the diameter φ_{2A} of the tapered shape hole part 12A (refer to FIG. 20C) in a location in which the wiring 22A formed on the smaller diameter side layer of the tapered shape hole part 12A is connected to the conductive film 14A. In addition, the diameter of the drill 52 is smaller than the diameter φ_{2B} of the tapered shape hole part 12B (refer to FIG. 20C) in a location in which the wiring 22B formed on the smaller diameter side layer of the tapered shape hole part 12B is connected to the conductive film 14B. Accordingly, a part of the wall surface 12a of the tapered shape hole part 12A, in which the diameter of the tapered shape hole part 12A is smaller than φ_{2A}, is cut and removed together with the conductive film 14A which covers the part of the wall surface 12a. In contrast, a part of the wall surface 12a of the tapered shape hole part 12A, in which the diameter of the tapered shape hole part 12A is equal to or larger than φ_{2A}, and the conductive film 14A which covers the part of the wall surface 12a do not come into contact with the drill 52, and thus the part of the wall surface 12a and the conductive film 14A remain without being cut.

Since the diameter of the tapered shape hole part 12A in the depth location of the wiring layer, on which the wirings 21A and 22A are formed, is equal to or larger than φ_{2A}, the wiring 21A and the wiring 22A are not damaged in the cutting process. It is similar to the conductive film 14A between the wiring 21A and the wiring 22A.

In the same manner, a part of the wall surface 12b of the tapered shape hole part 12B, in which the diameter of the tapered shape hole part 12B is smaller than φ_{2B} (refer to FIG. 20C), is cut and removed together with the conductive film 14B which covers the part of the wall surface 12b. In contrast, a part of the wall surface 12b of the tapered shape hole part 12B, in which the diameter of the tapered shape hole part 12B is equal to or larger than φ_{2B}, and the conductive film 14B which covers the part of the wall surface 12b do not come into contact with the drill 52, and thus the part of the wall surface 12b and the conductive film 14B remain without being cut. Since the diameter of the tapered shape hole part 12B in the depth location of the wiring layer, on which the wirings 21B and 22B are formed, is equal to or larger than φ_{2B}, the wiring 21B and the wiring 22B are not damaged in the cutting process. It is similar to the conductive film 14B between the wiring 21B and the wiring 22B.

As illustrated in FIG. 20C, the stub 16 (refer to FIG. 20A) is cut and removed using the drill 52. Therefore, the conductive films 14A and 14B are separated, a pair of the wiring 21A and the wiring 22A is divided from a pair of the wiring 21B and the wiring 22B. In addition, the cylindrical shape hole part 13, which communicates with the tapered shape hole parts 12A and 12B, is formed between the tapered shape hole parts 12A and 12B through cutting using the drill 52. The base 11, which is an insulator, is exposed in the wall surface 13a of the cylindrical shape hole part 13. The diameter φ₁ of the cylindrical shape hole part 13 is smaller than the diameter φ_{2A} of the tapered shape hole part 12A in a location in which the wiring 22A, formed on a wiring layer on the smaller diameter side of the tapered shape hole part 12A, is connected to the conductive film 14A.

In addition, the diameter φ₁ of the cylindrical shape hole part 13 is smaller than the diameter φ_{2B} of the tapered shape hole part 12B in a location in which the wiring 22B, formed on a wiring layer on the smaller diameter side of the tapered shape hole part 12B, is connected to the conductive film 14B. When the difference between the diameter φ₁ and the diameters φ_{2A} and φ_{2B} is reduced, it is possible to approximately completely remove the stub 16 (refer to FIG. 20A) without damaging the wirings 22A and 22B.

In the print substrate 10A and the manufacturing method thereof according to the second embodiment, it is possible to collectively form a tapered shape via hole, which includes the tapered shape hole part 12A and the conductive film 14A, and a tapered shape via hole which includes the tapered shape hole part 12B and the conductive film 14B.

In addition, similarly to the case according to the first embodiment, in the print substrate 10A and the manufacturing method thereof according to the second embodiment, when the attachment location of the drill 52 with regard to the machine tool changes, it is possible to usually acquire a fixed finishing state without changing the cutting part. That is, it is possible to approximately completely remove the stub without damaging the conductive film, which connects between the wirings, regardless of the location accuracy of the drill 52 in the stroke direction.

In addition, in the print substrate 10A and the manufacturing method thereof according to the second embodiment, the insertion direction of the drill 52, which is used to remove the stub, with regard to the base 11 is not limited, and thus it is possible to improve the flexibility of a manufacturing process, similarly to the first embodiment.

### Third Embodiment

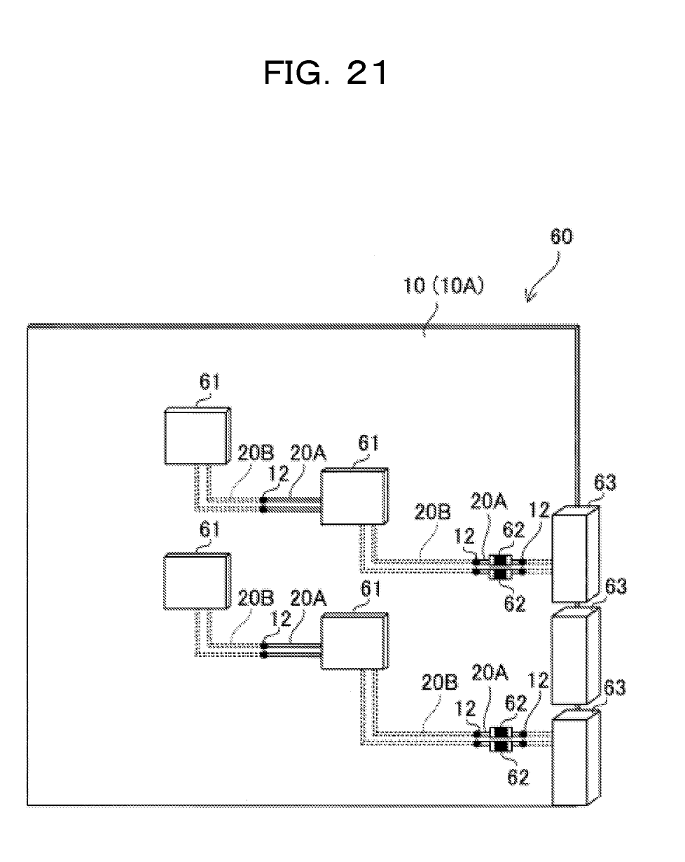

FIG. 21 is a perspective view illustrating an example of the configuration of an electronic unit 60 according to a third embodiment of the disclosed technology using the print substrate 10 according to the first embodiment or the print substrate 10A according to the second embodiment. As an example, the electronic unit 60 may be configured in such a way that electronic components, such as plural semiconductor devices 61 and plural chip capacitors 62, are mounted on the print substrate 10 (10A) as illustrated in FIG. 21. The semiconductor devices 61 may form an integrated circuit which realizes a desired function, and may be, for example, a central processing unit (CPU), a memory, a drive, a power integrated circuit (IC), or the like.

The plural semiconductor devices 61 may have different functions. The print substrate 10 (10A) includes a wiring 20A, which is formed on the surface of the print substrate 10 (10A), and a wiring 20B which is formed inside the print substrate 10 (10A). The wiring 20A and the wiring 20B are connected through a via hole which is formed while including a tapered shape hole part 12. The semiconductor devices 61 are connected to other semiconductor devices 61 or the chip capacitors 62 through the wiring 20A and the wiring 20B. The electronic unit 60 includes connectors 63 which are formed along the side of the print substrate 10 (10A). The connectors 63 are connected to the semiconductor devices 61 through the wirings 20A and 20B and the chip capacitors 62.

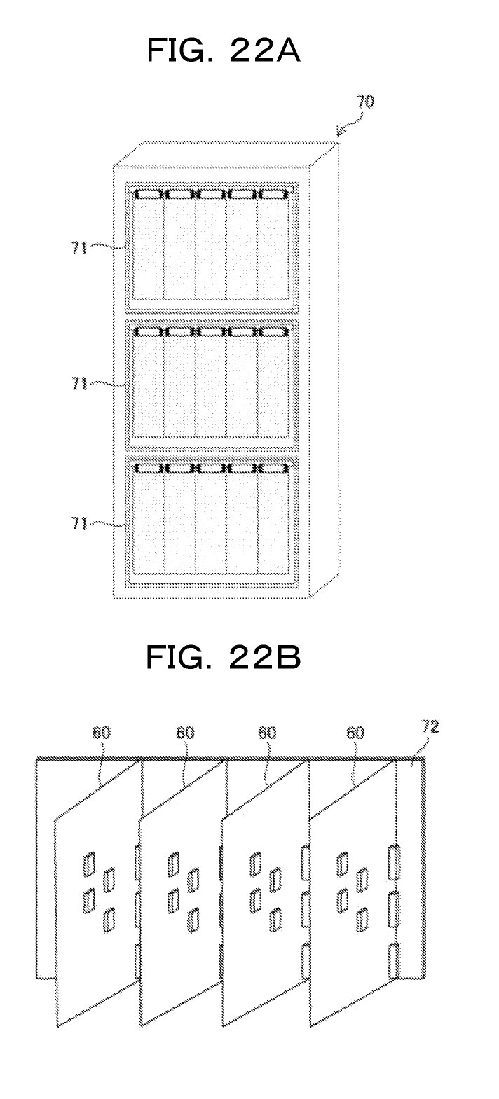

FIG. 22A is a perspective view illustrating an electronic device 70, which includes plural shelves 71 that respectively accommodate plural electronic units 60, according to the embodiment of the disclosed technology. FIG. 22B is a perspective view illustrating the plural electronic units 60 that are included in the respective shelves 71.

As illustrated in FIG. 22B, each of the plural electronic units 60 is accommodated in each of the shelves 71 in a state in which the plural electronic units 60 are attached to a back wiring board 72. Plural connectors (not illustrated in the drawing) corresponding to each of the plural electronic units 60 are formed on the back wiring board 72. When the connectors 63 of the electronic unit 60 are engaged, the respective plural electronic units 60 are connected to wirings (not illustrated in the drawing) which are formed on the back wiring board 72. For example, the electronic device 70 may be an information processing device such as a server computer or may be a transmission device which performs signal transmission.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A print substrate comprising:
a base;
a tapered shape hole that is formed in the base, and is configured to have a diameter which continuously changes along a thickness direction of the base;
a conductive film that covers a wall surface of the tapered shape hole;
a plurality of wirings that are formed in locations which are different from each other in the thickness direction of the base, and that are connected to the conductive film; and
a cylindrical shape hole that communicates with the tapered shape hole on a smaller diameter side of the tapered shape hole, and that has a smaller diameter than the diameter of the tapered shape hole in the locations in which the wirings, formed on the smaller diameter side of the tapered shape hole, of the plurality of wirings are connected to the conductive film.

2. The print substrate according to claim 1,
wherein the tapered shape hole, the conductive film, and the plurality of wirings are formed on both surfaces of the base while interposing the cylindrical shape hole therebetween.

3. The print substrate according to claim 1,
wherein the tapered shape hole has a truncated cone shape.

4. The print substrate according to claim 1,
wherein the tapered shape hole has a taper angle that is determined according to the locations of the plurality of wirings connected to the conductive film which covers the wall surface of the tapered shape hole in the thickness direction of the base.

5. The print substrate according to claim 1,
wherein the cylindrical shape hole has the diameter that is determined according to the locations of the plurality of wirings which are connected to the conductive film which covers the wall surface of the tapered shape hole communicating with the cylindrical shape hole in the thickness direction of the base.

6. An electronic device comprising:
a print substrate including
a base;
a tapered shape hole that is formed in the base, and is configured to have a diameter which continuously changes along a thickness direction of the base;
a conductive film that covers a wall surface of the tapered shape hole;
a plurality of wirings that are formed in locations which are different from each other in the thickness direction of the base, and that are connected to the conductive film; and
a cylindrical shape hole that communicates with the tapered shape hole on smaller diameter side of the tapered shape hole, and that has a smaller diameter than the diameter of the tapered shape hole in the locations in which the wirings, formed on the smaller diameter side of the tapered shape hole, of the plurality of wirings are connected to the conductive film; and
electronic components that are mounted on the print substrate.

7. The electronic device according to claim 6,
wherein, in the print substrate, the tapered shape hole, the conductive film, and the plurality of wirings are formed on both surfaces of the base while interposing the cylindrical shape hole therebetween.

8. The electronic device according to claim 6,
wherein the tapered shape hole has a truncated cone shape.

9. The electronic device according to claim 6,
wherein the tapered shape hole has a taper angle that is determined according to the locations of the plurality of wirings connected to the conductive film which covers the wall surface of the tapered shape hole in the thickness direction of the base.

10. The electronic device according to claim 6,
wherein the cylindrical shape hole has the diameter that is determined according to the locations of the plurality of wirings which are connected to the conductive films which cover the wall surfaces of the tapered shape holes communicating with the cylindrical shape hole in the thickness direction of the base.

11. A method of manufacturing a print substrate comprising:
forming a tapered shape hole that has a diameter which continuously changes along a thickness direction of a base in the base;
forming a conductive film on a wall surface of the tapered shape hole, and connecting a plurality of wirings that are formed in locations which are different from each other in the thickness direction of the base through the conductive film; and
forming a cylindrical shape hole that communicates with the tapered shape hole by partially cutting the wall surface of the tapered shape hole on a small diameter side together with the conductive film such that a diameter of the cylindrical shape hole is smaller than the diameter of the tapered shape hole in the locations in which the wirings, formed on a smaller diameter side of the tapered shape hole, of the plurality of wirings are connected to the conductive film.

12. The method of manufacturing a print substrate according to claim 11,
wherein the forming the tapered shape hole includes forming the tapered shape hole using a cone shape drill.

13. The method of manufacturing a print substrate according to claim 11,
wherein the forming the cylindrical shape hole includes forming the cylindrical shape hole by inserting a cylindrical drill into the tapered shape hole.

14. The method of manufacturing a print substrate according to claim 11,
wherein the forming the tapered shape hole includes forming two tapered shape holes, which have smaller diameter sides on an inner side of the base, on both sides of the base such that the tapered shape holes are concentric with each other,
wherein the forming the conductive film includes forming the conductive films on respective wall surfaces of the two tapered shape holes, and
wherein the forming the cylindrical shape hole includes forming the cylindrical shape hole between the two tapered shape holes by inserting a cylindrical drill into the two tapered shape holes.

15. The method of manufacturing a print substrate according to claim 11, further comprising:
determining a taper angle of the tapered shape hole according to the locations of the plurality of wirings connected to the conductive films which cover the wall surfaces of the tapered shape holes in the thickness direction of the base.

16. The method of manufacturing a print substrate according to claim 11, further comprising:
determining the diameter of the cylindrical shape hole according to the locations of the plurality of wirings connected to the conductive films which cover the wall surfaces of the tapered shape holes communicating with the cylindrical shape hole in the thickness direction of the base.
